(19) United States
(12) Patent Application Publication
(10) Pub. No.: US 2024/0355728 A1
(43) Pub. Date: Oct. 24, 2024

(54) SEMICONDUCTOR STRUCTURE

(71) Applicant: Taiwan Semiconductor Manufacturing Company, Ltd., Hsinchu (TW)

(72) Inventors: Kai-Chun Chang, Taichung City (TW); Hsieh-Hung Hsieh, Taipei City (TW); Tzu-Jin Yeh, Hsinchu City (TW); Ching-Chung Hsu, Hsinchu City (TW); Chung-Long Chang, Hsinchu City (TW); Hua-Chou Tseng, Hsinchu City (TW)

(21) Appl. No.: 18/451,263

(22) Filed: Aug. 17, 2023

Related U.S. Application Data
(60) Provisional application No. 63/497,559, filed on Apr. 21, 2023.

(51) Int. Cl. H01L 23/522; H01L 23/00; H01L 23/528; H01L 23/532

(52) U.S. Cl. CPC H01L 23/5227; H01L 23/5283; H01L 23/5286; H01L 23/53219; H01L 23/53233; H01L 24/05; H01L 24/13; H01L 2224/02313; H01L 2224/02331; H01L 2224/0235; H01L 2224/02373; H01L 2224/02375; H01L 2224/02381; H01L 2224/0239; H01L 2224/05548; H01L 2224/05557; H01L 2224/13007; H01L 2924/30107

(57) ABSTRACT

A semiconductor structure includes a circuit with a redistribution layer (RDL) formed over the circuit. The redistribution layer comprises a plurality of metal layers. An inductor is formed in a topmost metal layer, and the circuit is located directly under the inductor. An under bump metallization (UBM) layer formed on the topmost metal layer and a conductive connector formed on the UBM layer.

### CROSS-REFERENCE TO RELATED APPLICATION

This application claims the benefit of commonly assigned U.S. Provisional Patent Application No. 63/497,559, filed on Apr. 21, 2023, which is incorporated by reference in its entirety.

### BACKGROUND

Semiconductor devices are used in a variety of electronic applications, such as, for example, personal computers, cell phones, digital cameras, and other electronic equipment in place of discrete circuits to reduce cost, and minimize size and complexity. Various integrated circuits are configured to operate at radio frequency (RF) bands. These integrated circuits often employ passive elements, which may be in the form of on-chip inductors. On-chip inductors are usually coils or spirals of wiring which are patterned in the top level of the integrated circuit. The inductor carries varying current at high operating frequencies, which generates a magnetic field that can penetrate into the substrate below. The magnetic field induces an eddy current within the substrate, which flows in an opposite direction as the inductor current. The eddy current generates its own magnetic field, which opposes the magnetic field of the inductor, thereby lowering the quality factor (Q) of the inductor. Q is a commonly used indicator of inductor performance in an integrated circuit device. Q varies as a function of frequency and is a measurement of an inductor's relationship between power loss and energy loss.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 is a schematic section view conceptually illustrating an example of a semiconductor structure in accordance with disclosed embodiments.

FIG. 2 is a schematic top view illustrating an example of an integrated inductor and circuit of the structure shown in FIG. 1 in accordance with disclosed embodiments.

FIG. 3 is a close-up top view illustrating an example of a portion of the integrated inductor shown in FIG. 2.

FIG. 4 is a schematic section view conceptually illustrating another example of a semiconductor structure in accordance with disclosed embodiments.

FIG. 5 is a schematic top view illustrating an example of an integrated inductor, patterned ground shield (PGS) and circuit of the structure shown in FIG. 4 in accordance with disclosed embodiments.

FIG. 6 is a close-up top view illustrating an example of a portion of the PGS shown in FIG. 5.

FIG. 7 is a flow diagram illustrating an example of a method in accordance with disclosed embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to a semiconductor structure that includes a circuit with a redistribution layer formed over the circuit. The redistribution layer has a plurality of metal layers, and an inductor is formed in a topmost metal layer of the metal layers. Further, the circuit is situated directly below the inductor. An under bump metallization (UBM) layer is formed on the topmost metal layer of the metal layers, and a conductive connector is formed on the UBM layer.

For some electrical circuits such RF transceivers, passive components such as inductors, transformers, baluns, etc. are often used. For instance, millimeter-wave (mm-wave) frequencies generally refer to radio frequency (RF) signals in the frequency band between approximately 30 GHz to 300 GHz, which are frequently used in various applications such as wireless personal area networks (WPANs), automobile radar, image sensing, etc. Various low noise amplifiers (LNAs) for RF circuits, including millimeter wave circuits, exist. For example, some millimeter-wave LNAs may be implemented using complementary metal oxide semiconductor (CMOS) cascode structures for multi-stage LNAs. Such LNA circuits typically employ impedance matching circuits including passive components such as inductors.

These passive components can consume much chip area resulting in increased costs, especially in advanced CMOS technology nodes. An integrated inductor is typically realized by using an ultra-thick metal (Mu) layer to minimize the inductor loss. On-chip inductors may include coils or spirals of wiring that are patterned in the top level of the integrated circuit. The inductor carries varying current at high operating frequencies, which generates a magnetic field that can penetrate into the substrate below. The magnetic field induces an eddy current within the substrate, which flows in an opposite direction as the inductor current. The eddy current generates its own magnetic field, which opposes the magnetic field of the inductor, thereby lowering the quality factor (Q) of the inductor. Q is a commonly used indicator of inductor performance in an integrated circuit device. Q varies as a function of frequency and is a measurement of an inductor's relationship between power loss and energy loss.

Design rules often do not allow circuit placement directly under integrated inductors. Although the Mu layer is thicker than the remaining metal layers of a redistribution layer (RDL) to reduce or minimize inductor loss, the coupling can still be large. Therefore, placement of the circuit in the area directly below the inductor is not allowed. Since the inductor occupies a significant area of the chip, there can be a large unused area where circuits are not placed (i.e. directly below the inductor), resulting in increased area penalty and cost.

In some disclosed examples, to reduce the chip area, circuits of a semiconductor structure are positioned directly under a passive component such as an inductor, transformer, balun, etc. that is formed in an RDL conductive layer, such as a Cu-RDL backend metal layer. A pattern ground shielding (PGS) may also be employed to reduce the coupling effects. The Cu-RDL layer is used to enhance inductor performance, and the shielding is used to avoid vertical coupling. As such, circuit placement directly under an integrated passive device such as an inductor is feasible to save chip area.

In some known conventional implementations of integrated inductors, the inductor is formed in a Cu Mu layer below an uppermost aluminum (Al) layer. In one disclosed embodiment, a thick Cu-RDL backend metal layer in which the inductor is formed is provided above a Cu Mu layer. This increases the separation or distance between the inductor and the lossy substrate, and the inductor coil formed by the thick Cu-RDL layer reduces resistance (the resistance of Cu is lower than that of Al), thus reducing substrate loss. Thus, the thick Cu layer can improve the Q factor of the formed inductor.

Some examples further employ PGS that may include a slotted pattern, which reduces the negative mutual coupling. The slotted pattern acts as an open circuit and cuts off eddy currents. The PGS area does not form a closed loop around the coil of the inductor, which could potentially produce an unwanted loop current. In conventional processes, a PGS may formed in a lower metal layer (e.g. M1 or M2 layer). With disclosed embodiments, the PGS is formed in an Mz layer, where z>2. In such examples employing PGS, the topmost layer may be made of a conductive metal layer other than Cu, since the PGS reduces coupling.

Still further examples combine the PGS with a thick Cu-RDL topmost layer that forms the inductor to further enhance inductor performance (i.e. avoid vertical coupling), such that circuit placement directly under the inductor may be realized.

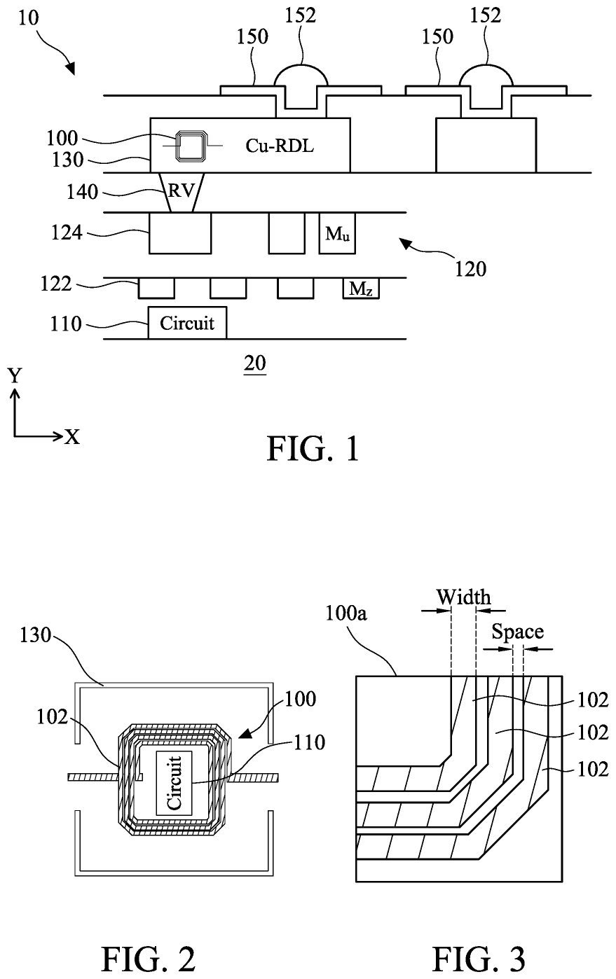

FIG. 1 is a schematic section view conceptually illustrating an example of a semiconductor structure 10 that includes an integrated passive component, such as an inductor 100. In the illustrated example, the semiconductor structure 10 includes a circuit 110 formed in or on a substrate 20. In some implementations, the substrate 20 is a semiconductor substrate, such as a silicon substrate, although it may include other semiconductor materials, such as silicon germanium, silicon carbide, gallium arsenide, or the like. The substrate 20 could be a p-type semiconductor substrate (P-Substrate) or an n-type semiconductor substrate (N-Substrate) comprising silicon. Alternatively, the substrate 20 could include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In yet another alternative, the substrate 20 is a semiconductor on insulator (SOI). In other alternatives, semiconductor substrate 20 may include a doped epi layer, a gradient semiconductor layer, and/or a semiconductor layer overlying another semiconductor layer of a different type, such as a silicon layer on a silicon germanium layer. The substrate 20 may or may not include doped regions, such as a p-well, an n-well, or combination thereof.

A circuit 110 is formed in or on the substrate 20. As will be discussed further herein below, the circuit 110 is positioned directly under a passive component such as an inductor 100 (i.e. below the inductor 100 in the vertical or y direction and aligned or overlapping laterally in the x direction as shown in FIG. 1). In contrast, known arrangements with an integrated inductor may have a “forbidden region” directly under the inductor where circuits may not be located to prevent vertical coupling. This “unusable” space can result in decreased chip usage, which can increase costs.

Although not specifically shown for the sake of simplicity, the circuit 110 may include a plurality of electronic components formed in or on the substrate 20. For example, source and drain regions of Field Effect Transistor (FET) devices may be formed in the substrate 20. The source and drain regions may be formed by one or more ion implantation or diffusion processes. As another example, isolation structures such as shallow trench isolation (STI) structures or deep trench isolation (DTI) structures may be formed in the substrate to provide isolation for the various electronic components. These isolation structures may be formed by etching recesses (or trenches) in the substrate 20 and thereafter filling the recesses with a dielectric material, such as silicon oxide, silicon nitride, silicon oxy-nitride, fluoride-doped silicate (FSG), and/or a low-k dielectric material known in the art. For the sake of simplicity, the various electronic components formed in the substrate 20 are not specifically illustrated herein.

Examples of the circuit 110 further include an interconnect structure with a plurality of patterned dielectric layers and interconnected conductive layers. These interconnected conductive layers provide interconnections (e.g., wiring) between circuitries, inputs/outputs, and various doped features formed in the substrate 20. Such an interconnect structure may include a plurality of interconnect layers, also referred to as metal layers. Throughout the description, the term “metal layer” refers to a collection of metal lines formed in the same layer. Each of the interconnect layers includes a plurality of interconnect features, also referred to as metal lines. The metal lines may be aluminum interconnect lines or copper interconnect lines, and may include conductive materials such as aluminum, copper, aluminum alloy, copper alloy, aluminum/silicon/copper alloy, titanium, titanium nitride, tantalum, tantalum nitride, tungsten, polysilicon, metal silicide, or combinations thereof. The metal lines may be formed by a process including PVD, CVD, sputtering, plating, or combinations thereof.

The interconnect structure further includes an interlayer dielectric (ILD) that provides isolation between the interconnect layers. The ILD may include a dielectric material such as an oxide material. The interconnect structure also includes a plurality of vias/contacts that provide electrical connections between the different interconnect layers and/or the features on the substrate. For the sake of simplicity, the metal lines in the interconnect layers, the vias interconnecting the metal lines, and the dielectric material separating them are not specifically illustrated herein.

An RDL 120 is formed over the circuit 110, which may include one or more conductive layers, such as metal layers 122 (i.e. Mz layer(s)). For ease of illustration, FIG. 1 representatively illustrates a single RDL metal layer 122 (Mz), though the RDL 120 may include a plurality of metal layers M1-Mz in some embodiments. The RDL 120 further includes an Mu layer 124 over the RDL metal layer 122.

In some examples, the RDL 120 includes insulating layers (not shown in FIG. 1) in addition to the metal layers 122, 124. The insulating layers may be positioned between adjacent metal layers 122. The insulating layers may include a polymer, which may be a photo-sensitive material such as PBO, polyimide, BCB, or the like, that may be patterned using a lithography mask. In other embodiments, the insulating layers may be formed of a nitride (e.g., silicon nitride), an oxide (e.g., silicon oxide), a glass (e.g., PSG, BSG. BPSG), a dielectric material, and/or the like, or a combination thereof. The insulating layers may be formed by spin coating, lamination, CVD, or the like, or a combination thereof.

The insulating layers may be patterned by any suitable process, such as by employing lithographic exposure of a photo-sensitive material, followed by development and etching; e.g., an anisotropic etch. If the insulating layers are a photo-sensitive material, they can be patterned by exposing, developing, and curing the photosensitive material in accordance with the desired pattern.

The metal layers 122, 124 may include metallization patterns with vias formed on or through appropriate insulating layers. For example, a seed layer (not shown) may be formed over and in openings through a given insulating layer. In some embodiments, the seed layer may comprise a metal layer, which may be a single layer or a composite layer having a plurality of sub-layers formed of different materials. In some embodiments, the seed layer comprises a titanium layer and a copper layer over the titanium layer. The seed layer may be formed using, for example, PVD, or the like. Photoresist may then be formed and patterned on the seed layer. The photoresist may be formed by spin coating, or the like, and may be exposed to light for patterning. The pattern of the photoresist corresponds to subsequently formed metallization pattern. Patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, e.g., copper, titanium, tungsten, aluminum, or the like. Thereafter, photoresist and portions of the seed layer on which the conductive material is not formed are removed. The photoresist may be removed by an acceptable ashing or stripping process, e.g., using an oxygen plasma, or the like. Once the photoresist is removed, exposed portions of the seed layer may be removed, such as by using an acceptable etching process, e.g., wet or dry etching. Remaining portions of the seed layer and conductive material form the metallization pattern with vias. The vias of metallization pattern are formed in openings through the insulating layers to electrical connectors of the circuit 110.

In the example of FIG. 1, the RDL includes the Mu layer 124, which is positioned over (i.e. vertically or in the y direction) the RDL metal layer 122. In some examples, the Mu layer 124 is at least 3 μm thick (i.e. thickness in the y direction) and in further examples the Mu layer 124 is at least 5 μm thick. The other RDL layer(s) 122 are 0.5-1 μm thick. Thus, in some examples, the Mu layer 124 is at least 3× thicker than the Mz layer 122. In some embodiments, the Mu layer includes copper, though in other embodiments the Mu layer may include aluminum, gold, silver and known alloys, some of which include copper.

The Mu layer 124 may be formed in a back-end-of-line (BEOL) operation. In the example of FIG. 1, the Mu layer 124 includes copper, though in other embodiments the Mu layer 124 includes aluminum, gold, silver and known alloys, some of which include copper. Conductive lines of the Mu layer 124 may be surrounded by a dielectric material that has a thickness substantially identical to the thickness of the Mu layer 124.

The inductor 100 is formed in a topmost metal layer 130 (i.e. in the y direction) of the RDL 120. In the illustrated example, the topmost metal layer is 130 directly over the Mu layer. A via 140 connects the topmost metal layer 130 to the Mu layer 124. As noted above, the inductor 100 is formed in the topmost metal layer 130 such that the circuit 110 directly under the inductor 100. In other words, in the illustrated example, the inductor 100 fully overlaps the circuit 110 when viewed from above in the y direction as shown in the conceptual top view of FIG. 2.

In the example shown in FIG. 1, the topmost metal layer 130 is a Cu layer positioned over (i.e. vertically or in the y direction) the Mu metal layer 124. In some examples, the topmost metal layer 130 is at least 3 μm thick (i.e. thickness in the y direction) and in further examples the topmost metal layer 130 is at least 7 μm thick. Moreover, in some examples the topmost metal layer 130 is thicker than the Mu layer 124.

As noted above, the topmost layer 130 in which the inductor 100 is formed is situated directly above the Mu layer 124 in the illustrated embodiment. After formation of the Mu layer 124, in some examples a first etch stop layer is formed over, and may contact, metal lines in the Mu layer 124. The first etch stop layer may be formed of silicon nitride, for example, although other dielectric materials may be used.

A via-dielectric layer may be formed over the first etch stop layer, followed by the deposition of a second etch stop layer. The via-dielectric layer may be formed of an oxide such as Un-doped Silicate Glass (USG), Fluorinated Silicate Glass (FSG), a low-k oxide, or the like, and the subsequent second etch stop layer may be formed of silicon nitride or another dielectric material. The second etch stop layer and via-dielectric layer are then patterned, followed by the etching of the first etch stop layer to form via openings for the via 140 providing electrical connection between the topmost layer 130 and lower layers Mu 124 and Mz 122.

A topmost layer dielectric may be formed of USG, FSG, Low-K material, or the like. Openings are formed through the topmost layer dielectric, and in a subsequent step, a metallic material, which may comprise copper or a copper alloy, is filled into the openings to form the inductor 100. A planarization such as a chemical mechanical polish (CMP) may be performed to remove the excess metal over the topmost layer dielectric, leaving thick conductive lines 102 that form the inductor 100.

As shown in the example of FIG. 2, the inductor 100 may thus include the conductive lines 102 formed as a spiral-shaped coil. FIG. 3 is a close up view of a portion of the inductor 100, in which the conductive lines 102 have a width of about 1.5-3.0 μm, and are separated from adjacent lines 102 by a space of about 2.0-6.0 μm.

An under bump metallization (UBM) layer 150 is formed on the topmost metal layer 130. In some examples, the UBM layer 150 is formed directly over the uppermost metal layer 130 and is electrically connected thereto. For example, structure over the topmost metal layer 130 may include a passivation layer, a metal pad connected to connectors of the topmost metal layer 130 and a further passivation layer. The metal pad may include aluminum, aluminum copper, tungsten, and/or the like. The UBM 150 extends into an opening in the passivation layer. A conductive connector, such as a metal bump 152 is then formed on the UBM 150. The metal bump 152 may be a solder bump or a bump comprising copper, nickel, palladium, and/or the like.

Thus, with the example of FIGS. 1-3, overall chip area is reduced by positioning the circuit 110 directly under the passive component (i.e. inductor 100), which is formed in the topmost RDL layer 130. Further, forming the inductor in a thick Cu RLD layer enhances performance of the inductor 100 and reduces vertical coupling, since resistance is reduced (e.g. as compared to Al and/or thinner conductor of the inductor coil) and the vertical distance between the inductor 100 and circuit 110 is increased.

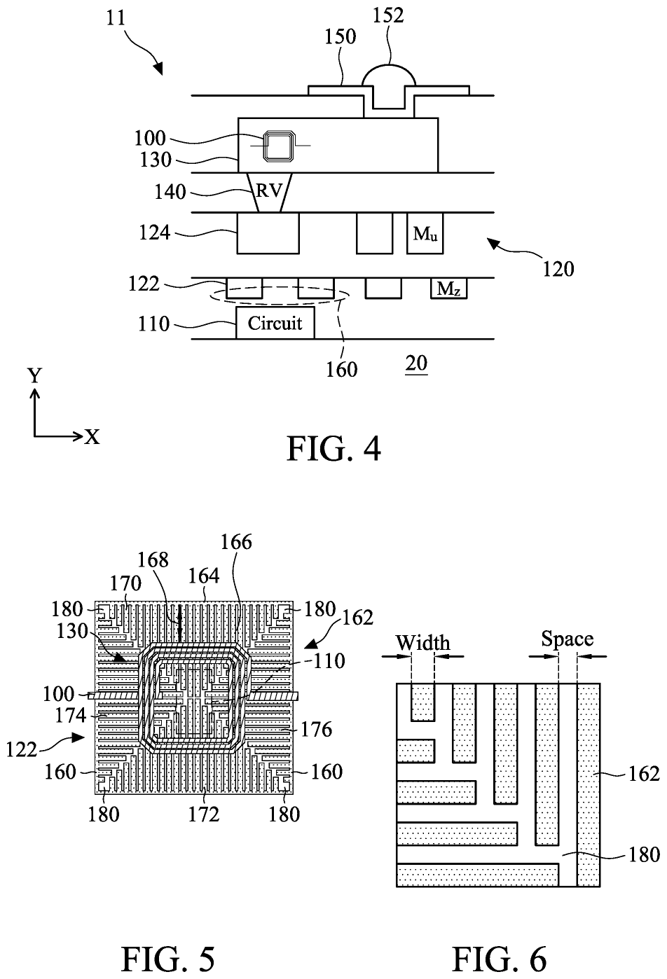

FIG. 4 is a schematic section view conceptually illustrating another embodiment of a semiconductor structure 11 that includes an integrated passive component, such as the inductor 100. Aspects of the semiconductor structure 11 that are similar to those of the example shown in FIG. 1 may not be discussed in detail in conjunction with FIG. 4 for the sake of brevity.

In the example illustrated in FIG. 4, the semiconductor structure 11 includes a circuit 110 formed in or on a substrate 20 as with the semiconductor structure 10 shown in FIGS. 1-3. The semiconductor structure 11 includes an RDL 120 formed over the circuit 110 similarly to that shown in FIG. 1. The RDL 120 of the example shown in FIG. 1 further includes a patterned ground shield (PGS) 160 formed between the inductor 100 and the circuit 110. In the illustrated example, the PGS 160 is formed in an Mz layer 124 where z>2. In other words, the PGS 160 is formed in metal layer M3 or higher. However, the disclosure is not limited to a PGS formed in metal layer M3 or higher. In other implementations the PGS 160 may be formed in an M1 or M2 metal layer.

The PGS 160 is formed with patterned metal lines in one or more of the metal layers Mz. The PGS 160 isolates the inductor 100 from components of the circuit 110. FIG. 5 is a top view illustrating the inductor 100 formed in the topmost layer 130 above the PGS 160 formed in the Mz layer 122. The PGS 160 includes a plurality of conductors 162 arranged in a slotted pattern. In the example of FIG. 5, the conductors 162 are located in an upper quadrant 170, a lower quadrant 172, a left quadrant 174 and a right quadrant 176. The conductors 162 of the upper quadrant 170 and the lower quadrant 172 extend vertically (i.e. the y direction), while the conductors 162 of the left quadrant 174 and the right quadrant 176 extend horizontally (i.e. the x direction). The conductors 162 of adjacent quadrants are electrically isolated from one another by diagonally extending isolation structures 180, which include a suitable dielectric material, for example. Thus, the conductors 162 act as an open circuit to cut off eddy currents, and because the conductors 162 of adjacent quadrant are separated by the isolation structures 180 they do not form a closed loop or continuous spiral which could produce an unwanted loop current.

FIG. 6 is a close up view showing a portion of some of the conductors 162. In some embodiments, the conductors define a width of 0.2-3.0 μm. Moreover, adjacent conductors are separated by a space of 0.2-3.0 μm, though other line widths and spaces are within the scope of the disclosure. In some embodiments, the space is 5× the width in some examples, and in other examples the space is 3× the width to improve the inductor Q factor. Other relationships between the conductor and the space separating the conductors are within the scope of the disclosure.

In accordance with further embodiments, the PGS 160 is symmetrically positioned around the inductor 100 as shown in FIG. 5. In other words, the distance between a sidewall surface 164 of the outermost pattern (i.e. the outer edge PGS structure 160) and the sidewall surface 166 (i.e. outer edge of outer conductor) of the inductor loop 100 is the same or approximately the same on each side of the PGS 160 and inductor 100. In some examples, this “enclosure” dimension 168 is 2.0-75 μm to increase the inductor Q factor. However, other enclosure dimensions are within the scope of the disclosure.

As with the example shown in FIGS. 1-3, the circuit 110 shown in FIGS. 4 and 5 is positioned directly under the inductor 100. In other words, as shown in the top view of FIG. 5, the inductor 100 and PGS 160 fully overlap the circuit 110 when viewed in the y direction (i.e. when viewed from the top). This provides a more efficient use of device space, and is facilitated by the provision of the PGS 160, among other things. Since the PGS 160 reduces coupling between the inductor 100 and circuit 110, thus improving performance of the inductor 100, the conductor 100 may be formed in a topmost layer 130 made of a conductor other than Cu, such as Al. Moreover, with the improved inductor 100 performance resulting from provision of the PGS 160, the inductor 100 could be formed in a thinner topmost layer 130. In other words, the topmost layer 130 in the example of FIG. 4 could be thinner that that of the FIG. 1 example.

However, some embodiments employ both a thick Cu topmost layer 130 in which the inductor 100 is formed, is used together with the PGS 160 to achieve the combined benefits of both aspects.

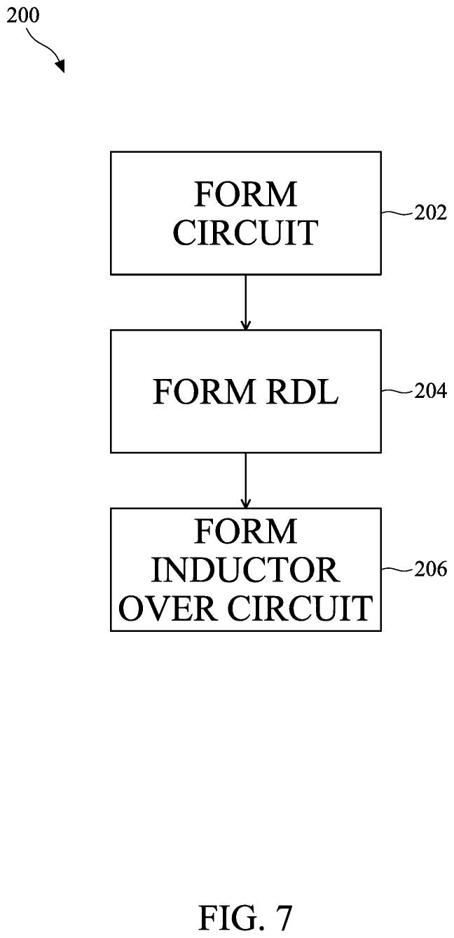

FIG. 7 is a flow diagram illustrating aspects of an example method 200 for forming a semiconductor structure (such as the semiconductor structures 10 and/or 11) in accordance with some embodiments. Referring to FIG. 7 together with the figures discussed above, a circuit 110 is formed on or in a substrate 20 at operation 202. In disclosed embodiments, the substrate 20 is a semiconductor substrate, such as a silicon substrate, although it may include other semiconductor materials, such as silicon germanium, silicon carbide, gallium arsenide, or the like. The substrate 20 could be a P-Substrate or an N-Substrate comprising silicon. Other embodiments employ a substrate 20 with another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In yet another alternative, the substrate 20 is a semiconductor on insulator (SOI). The semiconductor substrate 20 could also include a doped epi layer, a gradient semiconductor layer, and/or a semiconductor layer overlying another semiconductor layer of a different type, such as a silicon layer on a silicon germanium layer. The substrate 20 may or may not include doped regions, such as a p-well, an n-well, or combination thereof.

The circuit 110 formed in or on the substrate 20 in operation 202 is positioned directly under a passive component (e.g. inductor 100) as shown in FIGS. 2 and 5. Thus, the circuit 110 is positioned below the inductor 100 in the vertical or y direction and aligned or overlapping laterally in the x direction as shown in FIGS. 1 and 4. This eliminates a “forbidden region” directly under the inductor sometimes required with conventional arrangements, in which circuits may not be located to prevent vertical coupling. This “unusable” space can result in decreased chip usage, which can increase costs.

The circuit 110 may include electrical components such as FET devices with source and drain regions formed by one or more ion implantation or diffusion processes, isolation structures such as shallow trench isolation (STI) structures or deep trench isolation (DTI) structures may formed by etching recesses (or trenches) in the substrate 20 and thereafter filling the recesses with a dielectric material, such as silicon oxide, silicon nitride, silicon oxy-nitride, fluoride-doped silicate (FSG), and/or a low-k dielectric material known in the art. The circuit 110 may further include an interconnect structure with a plurality of patterned dielectric layers and interconnected conductive layers. These interconnected conductive layers provide interconnections (e.g., wiring) between circuitries, inputs/outputs, and various doped features formed in the substrate 20. The interconnections may be in the form of aluminum interconnect lines or copper interconnect lines, and may include conductive materials such as aluminum, copper, aluminum alloy, copper alloy, aluminum/silicon/copper alloy, titanium, titanium nitride, tantalum, tantalum nitride, tungsten, polysilicon, metal silicide, or combinations thereof. The metal lines may be formed by a process including PVD, CVD, sputtering, plating, or combinations thereof.

The interconnect structure further includes an interlayer dielectric (ILD) that provides isolation between the interconnect layers. The ILD may include a dielectric material such as an oxide material. The interconnect structure also includes a plurality of vias/contacts that provide electrical connections between the different interconnect layers and/or the features on the substrate.

In operation 204, a RDL 120 is formed over the circuit 110. Forming the RDL 120 includes forming a plurality of metal layers Mz 122 over the circuit 110 and an Mu layer 124 that is at least 3 μm thick. In some examples, the Mu layer is at least 5 μm thick. The other RDL layer(s) 122 are 0.5-1 μm thick in illustrated examples. Thus, the Mu layer 124 is at least 3× thicker than the Mz layer(s) 122. In some embodiments, the Mu layer includes copper, though in other embodiments the Mu layer may include aluminum, gold, silver and known alloys, some of which include copper. Further, the Mu layer 124 is positioned over the Mz layer(s) 122 in the illustrated examples.

The RDL 120 includes insulating layers in addition to the metal layers 122, 124, which may be positioned between adjacent metal layers 122. The insulating layers may include a polymer, which may be a photo-sensitive material such as PBO, polyimide, BCB, or the like, that may be patterned using a lithography mask. In other embodiments, the insulating layers may be formed of a nitride (e.g., silicon nitride), an oxide (e.g., silicon oxide), a glass (e.g., PSG, BSG, BPSG), a dielectric material, and/or the like, or a combination thereof. The insulating layers may be formed by spin coating, lamination, CVD, or the like, or a combination thereof.

The insulating layers may be patterned by any suitable process, such as by employing lithographic exposure of a photo-sensitive material, followed by development and etching; e.g., an anisotropic etch. If the insulating layers are a photo-sensitive material, they can be patterned by exposing, developing, and curing the photosensitive material in accordance with the desired pattern.

The metal layers 122, 124 may include metallization patterns with vias formed on or through appropriate insulating layers. For example, a seed layer may be formed over and in openings through a given insulating layer. In some embodiments, the seed layer may comprise a metal layer, which may be a single layer or a composite layer having a plurality of sub-layers formed of different materials. In some embodiments, the seed layer comprises a titanium layer and a copper layer over the titanium layer. The seed layer may be formed using, for example, PVD, or the like. Photoresist may then be formed and patterned on the seed layer. The photoresist may be formed by spin coating, or the like, and may be exposed to light for patterning. The pattern of the photoresist corresponds to subsequently formed metallization pattern. Patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, e.g., copper, titanium, tungsten, aluminum, or the like. Thereafter, photoresist and portions of the seed layer on which the conductive material is not formed are removed. The photoresist may be removed by an acceptable ashing or stripping process, e.g., using an oxygen plasma, or the like. Once the photoresist is removed, exposed portions of the seed layer may be removed, such as by using an acceptable etching process, e.g., wet or dry etching. Remaining portions of the seed layer and conductive material form the metallization pattern with vias. The vias of metallization pattern are formed in openings through the insulating layers to electrical connectors of the circuit 110.

The Mu layer 124, which may include copper, aluminum, gold, silver and alloys, may be formed in a BEOL operation. Conductive lines of the Mu layer 124 may be surrounded by a dielectric material that has a thickness substantially identical to the thickness of the Mu layer 124.

An inductor 100 is formed in a topmost metal layer 130 of the plurality of metal layers in operation 206. As noted above, the inductor 100 is formed directly over the circuit 110. A via 140 connects the topmost metal layer 130 (including the inductor 100) to the Mu layer 124. In certain implementations, the topmost metal layer 130 is at least 3 μm thick (i.e. thickness in the y direction) and in further examples the topmost metal layer 130 is at least 7 μm thick. Moreover, in some examples the topmost metal layer 130 is thicker than the Mu layer 124.

After formation of the Mu layer 124, in some examples a first etch stop layer is formed over, and may contact, metal lines in the Mu layer 124. The first etch stop layer may be formed of silicon nitride, for example, although other dielectric materials may be used. A via-dielectric layer may be formed over the first etch stop layer, followed by the deposition of a second etch stop layer. The via-dielectric layer may be formed of an oxide such as Un-doped Silicate Glass (USG), Fluorinated Silicate Glass (FSG), a low-k oxide, or the like, and the subsequent second etch stop layer may be formed of silicon nitride or another dielectric material. The second etch stop layer and via-dielectric layer are then patterned, followed by the etching of the first etch stop layer to form via openings for the via 140 providing electrical connection between the topmost layer 130 and lower layers Mu 124 and Mz 122.

A topmost layer dielectric may be formed of USG, FSG, Low-K material, or the like. Openings are formed through the topmost layer dielectric, and in a subsequent step, a metallic material, which may comprise copper or a copper alloy, is filled into the openings to form the inductor 100. A planarization such as a chemical mechanical polish (CMP) may be performed to remove the excess metal over the topmost layer dielectric, leaving conductive lines 102 that form the inductor 100. Further, the conductive lines 102 may be formed as a spiral-shaped coil and have a width of about 1.5-3.0 μm, and be separated from adjacent lines 102 by a space of about 2.0-6.0 μm.

The method may further include forming a PGS between the circuit 110 and the inductor 100. The PGS 160 may be formed with patterned metal lines in one or more of the metal layers Mz 122 to isolate the inductor 100 from components of the circuit 110. The conductors 162 extend vertically (i.e. the y direction) in upper and lower quadrants 170, 172, and extend horizontally (i.e. the x direction) left and right quadrants 174, 176. The conductors 162 of adjacent quadrants are electrically isolated from one another by diagonally extending isolation structures 180, which include a suitable dielectric material, for example. The conductors 162 arranged in this manner act as an open circuit to cut off eddy currents, and because the conductors 162 of adjacent quadrant are separated by the isolation structures 180 they do not form a closed loop or continuous spiral that could produce an unwanted loop current. In some embodiments, the conductors define a width of 0.2-3.0 μm and adjacent conductors are separated by a space of 0.2-3.0 μm, though other line widths and spaces are within the scope of the disclosure. The space is 5× the width in some examples, and in other examples the space is 3× the width to improve the inductor Q factor.

The method may further include forming an UBM layer 150 over the topmost metal layer 130 such that the topmost metal layer 130 is in direct contact with the UBM layer 150. In some examples, the UBM layer 150 is formed directly over the uppermost metal layer 130 and is electrically connected thereto. For example, structure over the topmost metal layer 130 may include a passivation layer, a metal pad connected to connectors of the topmost metal layer 130 and a further passivation layer. The metal pad may include aluminum, aluminum copper, tungsten, and/or the like. The UBM 150 extends into an opening in the passivation layer. A conductive connector, such as a metal bump 152 is then formed on the UBM 150. The metal bump 152 may be a solder bump or a bump comprising copper, nickel, palladium, and/or the like.

Thus, with various embodiments disclosed herein, overall chip area is reduced by positioning the circuit 110 directly under the passive component (i.e. inductor 100), which is formed in the topmost RDL layer 130. Further, forming the inductor in a thick Cu RLD layer enhances performance of the inductor 100 and reduces vertical coupling, since resistance is reduced (e.g. as compared to Al and/or thinner conductor of the inductor coil) and the vertical distance between the inductor 100 and circuit 110 is increased. Further, providing the PGS 160 configured to fully overlap the circuit 110 and inductor 100 when viewed in the y direction (i.e. when viewed from the top) reduces coupling between the inductor 100 and circuit 110, thus improving performance of the inductor 100.

In accordance with aspects of the disclosure, a semiconductor structure includes a circuit and a redistribution layer (RDL) formed over the circuit. The redistribution layer comprises a plurality of metal layers. An inductor is formed in a topmost metal layer, wherein the circuit is directly under the inductor. An under bump metallization (UBM) layer is formed on the topmost metal layer, and a conductive connector is formed on the UBM layer.

In accordance with further aspects, a semiconductor structure includes a circuit and an ultra-thick metal (Mu) layer that is at least 3 μm thick. A redistribution layer (RDL) is formed over the circuit, and the redistribution layer includes a topmost metal layer over the Mu layer. An inductor is formed in the topmost metal layer, and the circuit is directly under the inductor.

In accordance with additional aspects of the disclosure, a method includes forming a circuit on or in a substrate, and forming a redistribution layer (RDL) over the circuit. The RDL includes a plurality of metal layers formed over the circuit, which include an ultra-thick metal (Mu) layer that is at least 3 μm thick. An inductor is formed in a topmost metal layer of the plurality of metal layers, and the inductor is formed directly over the circuit.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a circuit;
a redistribution layer (RDL) formed over the circuit, wherein RDL comprises a plurality of metal layers;
an inductor formed in a topmost metal layer, wherein the circuit is directly under the inductor;
an under bump metallization (UBM) layer formed on the topmost metal layer; and
a conductive connector formed on the UBM layer.

2. The semiconductor structure of claim 1, wherein the RDL includes a copper (Cu) metal layer.

3. The semiconductor structure of claim 1, wherein the UBM layer is in direct contact with the topmost metal layer.

4. The semiconductor structure of claim 1, further comprising a patterned ground shield.

5. The semiconductor structure of claim 1, wherein the topmost metal layer includes a Cu metal layer.

6. The semiconductor structure of claim 1, wherein the topmost metal layer includes an aluminum (Al) metal layer.

7. The semiconductor structure of claim 1, wherein the plurality of metal layers includes an ultra-thick metal (Mᵤ) layer that is at least 3 μm thick.

8. The semiconductor structure of claim 7, wherein the Mu layer is immediately below the topmost metal layer.

9. The semiconductor structure of claim 1, wherein the topmost metal layer is 3-7 μm thick.

10. The semiconductor structure of claim 1, further comprising a patterned ground shield between the circuit and the inductor.

11. A semiconductor structure, comprising:
a circuit;
an ultra-thick metal (Mu) layer at least 3 μm thick;
a redistribution layer (RDL) formed over the circuit, wherein the RDL includes a topmost metal layer over the Mu layer; and
an inductor formed in the topmost metal layer, wherein the circuit is directly under the inductor.

12. The semiconductor structure of claim 11, wherein the topmost metal layer includes a copper (Cu) metal layer.

13. The semiconductor structure of claim 11, wherein the topmost metal layer is 3-7 μm thick.

14. The semiconductor structure of claim 11, further comprising a patterned ground shield.

15. The semiconductor structure of claim 14, wherein the patterned ground shield is formed in an Mz metal layer, where z>2.

16. The semiconductor structure of claim 14, wherein the patterned ground shield includes a plurality of conductive lines each having a width of 0.2-3 μm, and wherein adjacent ones of the plurality of conductive lines are separated by a 0.2-3 μm space.

17. A method, comprising:
forming a circuit on or in a substrate;
forming a redistribution layer (RDL) over the circuit, including forming a plurality of metal layers over the circuit, wherein the plurality of metal layers include an ultra-thick metal (Mu) layer that is at least 3 μm thick; and
forming an inductor in a topmost metal layer of the plurality of metal layers, wherein the inductor is formed directly over the circuit.

18. The method of claim 17, further comprising forming a patterned ground shield between the circuit and the inductor.

19. The method of claim 17, further comprising forming an under bump metallization (UBM) layer over the topmost metal layer such that the topmost metal layer is in direct contact with the UBM layer.

20. The method of claim 17, wherein the topmost metal layer is at least 3 μm thick.
